(19) United States
(12) Patent Application Publication
(10) Pub. No.: US 2015/0255176 A1
(43) Pub. Date: Sep. 10, 2015

(54) MEMORY TEST ECC AUTO-CORRECTION OF FAILING DATA

(71) Applicant: Advantest Corporation, Tokyo (JP)

(72) Inventors: Matt HYDER, Boise, ID (US); Ken Hanh Duc LAI, Sunnyvale, CA (US); Michael JONES, San Carlos, CA (US); Alan S. KRECH, JR., Fort Collins, CO (US)

(73) Assignee: Advantest Corporation, Tokyo (JP)

(21) Appl. No.: 14/202,929

(22) Filed: Mar. 10, 2014

(51) Int. Cl. G11C 29/44; G11C 29/42

(52) U.S. Cl. CPC G11C 29/44; G11C 29/42

(57) ABSTRACT

A method according to one embodiment of the present invention for evaluating test results for a memory module. The method comprises reviewing contents of a test data stream for one or more sections of the memory module. A first counter is incremented when a defective portion is encountered in the test data stream for a first section of the one or more sections of the memory module. Each defective portion of the first section is marked as good in the test data stream so long as a first counter value is equal to or below a first threshold value. Data from the test data stream identifying defective portions of the first section are stored in an error cache for each remaining defective portion of the first section identified after the first counter passes a first threshold value.

### TECHNICAL FIELD

The present disclosure relates generally to the field of memory device testing and post-processing and more specifically to the field of improving yield efficiencies of memory device manufacturing.

### BACKGROUND

Conventional memory devices, such as a NAND flash memory, are manufactured with ever increasing memory densities. For example, NAND flash memory devices are reaching memory densities of 1 terra-bytes or higher. Along with this continual increase in memory density, the identification and correction of memory errors is able to further improve the manufactured yield of a given memory device through the use of error correction processes. For example, when portions of a memory device are shown during testing to be defective, these portions of memory, during later post-processing, may be repaired/replaced with redundant memory elements. A further process to improve the yield of memory devices is the use of error-correcting code memory (also known as error checking and correction memory, or ECC memory). ECC memory may be used to detect and correct corrupt data coming from defective memory cells. Such error correction occurs during run-time.

When the memory testing is complete, a bitmap is generated and stored in an error cache RAM. The bitmap stored in the error cache can be used to store the locations of the failing memory modules. With all defective bit/byte locations identified, a post-processing procedure can be utilized that oversees the repair of the defective sections of the memory cell with redundant elements. If a given memory device has ECC correctable sections, then the same post-processing procedures that are used to determine which sections can be repaired with available redundant elements, may also take into account the capabilities of the ECC correction sections of the memory device. The post-processing of the failing bits in the bitmap can increase the efficiency of the memory device.

However, there are several difficulties, as memory device capacities grow ever denser, the post-processing necessary to correct the defective memory cells (using a combination of ECC and redundant elements) takes longer and the amount of RAM needed to store the failing data into a bitmap has also increased. Currently, any possible ECC corrections have to be considered and acted upon after the testing has completed and as a separate testing step. Furthermore, while the memory cell failure data in the bitmap may be compressed, the size of the bitmap will still be substantial. These difficulties (error cache RAM size and post-processing test time duration) will increase as the size of the NAND flash memory device increases.

### SUMMARY OF THE INVENTION

Embodiments of this present invention provide solutions to the challenges inherent in analyzing and repairing defective memory cells. In a method according to one embodiment of the present invention, a method for evaluating test results for a memory module is disclosed. The method comprises reviewing contents of a test data stream for one or more sections of the memory module. A first counter is incremented when a defective portion is encountered in the test data stream for a first section of the one or more sections of the memory module. Each defective portion of the first section is marked as good in the test data stream so long as a first counter value is equal to or below a first threshold value. Data from the test data stream identifying defective portions of the first section are stored in an error cache for each remaining defective portion of the first section identified after the first counter passes a first threshold value.

In an apparatus according to one embodiment of the present invention, a memory module test apparatus comprises a first buffer operable to hold a test data stream for one or more sections of the memory module. The apparatus further comprises a test processor operable to review the test data stream for defective portions. A first counter is operable to increment each time the test processor encounters a defective portion in the test data stream. The test processor is further operable to mark each defective portion as good in the test data stream so long as a first counter value is equal to or below a first threshold value. Lastly, an error cache is operable to store data identifying the defective portions in the test data stream for each remaining defective portion identified after the first counter passes a first threshold value.

### BRIEF DESCRIPTION OF THE DRAWINGS

The present invention will be better understood from the following detailed description, taken in conjunction with the accompanying drawing figures in which like reference characters designate like elements and in which:

FIG. 1 illustrates a block diagram of a portion of a memory module test apparatus with a test analysis processor for pre-selecting failing portions of a memory module for ECC correction in accordance with an embodiment of the present invention;

FIG. 2 illustrates a flow diagram, illustrating computer executed steps to a process for pre-selecting failing portions of an ECC memory module for error correction in accordance with an embodiment of the present invention;

FIG. 3 illustrates a flow diagram, illustrating computer executed steps to a process for pre-selecting failing bits of an ECC memory module for error correction in accordance with an embodiment of the present invention;

FIG. 4 illustrates a flow diagram, illustrating computer executed steps to a process for filtering failure data for a section of a memory module in accordance with an embodiment of the present invention; and

FIG. 5 illustrates a flow diagram, illustrating computer executed steps to a process for filtering failure data for a section of a memory module in accordance with an embodiment of the present invention.

### DETAILED DESCRIPTION

Reference will now be made in detail to the preferred embodiments of the present invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail so as not to unnecessarily obscure aspects of the embodiments of the present invention. The drawings showing embodiments of the invention are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part. Generally, the invention can be operated in any orientation.

### Notation and Nomenclature:

Some portions of the detailed descriptions, which follow, are presented in terms of procedures, steps, logic blocks, processing, and other symbolic representations of operations on data bits within a computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “processing” or “accessing” or “executing” or “storing” or “rendering” or the like, refer to the action and processes of a computer system, or similar electronic computing device, that manipulates and transforms data represented as physical (electronic) quantities within the computer system's registers and memories and other computer readable media into other data similarly represented as physical quantities within the computer system memories or registers or other such information storage, transmission or display devices. When a component appears in several embodiments, the use of the same reference numeral signifies that the component is the same component as illustrated in the original embodiment.

### Memory Test ECC Auto-Correction of Failing Data:

Embodiments of this present invention provide solutions to the increasing challenges inherent in analyzing memory device testing results and selecting defective memory cells for repair with redundant elements and ECC memory correction. Various embodiments of the present disclosure provide pre-selection of defective bits/bytes for ECC memory correction. Embodiments of this invention allow on-the-fly analysis. As a memory device is being tested, and while results are coming in, a determination may be made as to whether or not the memory device is repairable/correctable with ECC memory correction, rather than waiting for post-processing.

By reviewing the test results for a current ECC section of a memory device, defective bits/bytes in the current ECC section can be reviewed, and based upon the number of defective bits/bytes and the number of possible ECC corrections for the current section, many of the bits/bytes currently labeled as defective can be relabeled as “good.” As discussed herein, the defective bits/bytes that were relabeled as good would be able to be handled through ECC memory correction at run-time. Therefore, for an ECC correctable section, if there are more ECC correction bits than there are defective bits in a section, then that section can be considered as fully passing and even if there are more failing bits than ECC correctable bits, only those bits that aren't corrected through ECC would still be considered as failing (and through post-processing, possibly repaired with redundant elements). Advantages to pre-selection of defective portions for ECC memory correction include test time savings and a smaller error cache. Test time savings is primary removing the need for post-processing to select defective memory cells for ECC memory correction, while the error cache size savings is possible because an error cache memory large enough to store a complete bitmap is not required.

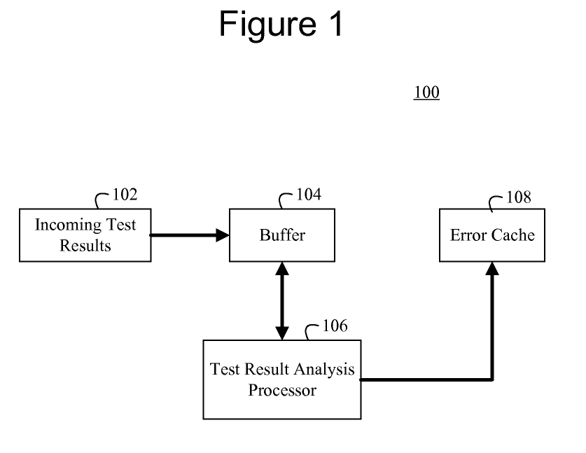

As illustrated in FIG. 1, test results 102 for a given section of a memory device are received and stored in a buffer 104. In one embodiment, a memory section may be a region, page, or plane. A test result analysis processor 106 reviews the test results 102 stored in the buffer 104. As discussed herein, as each defective portion (a defective portion may be a defective bit or a defective byte, depending on how the defects are being counted) is identified, a counter is incremented. If the current counter value is below the low threshold, the current defective portion will be relabeled as “good.” As discussed herein, as many defective portions as there are ECC correction bits to correct them may be relabeled as good, with some exceptions, as noted herein. When all of the test results 102 in the buffer 104 have been reviewed and as many of the defective portions have been relabeled as possible, the contents of the buffer 104 will be transferred to the error cache 108 for further post-processing after the testing process completes. The remaining defective portions identified in the error cache can be evaluated during the post processing for possible repair with redundant elements.

In one embodiment, a memory module test apparatus 100 utilizes several staging regions of memory or buffers, such as buffer 104 in FIG. 1. The buffer 104 is sized to hold a given section's worth of data. As the data 102 is being placed into the temporary buffer 104, the number of errors in the data 102 is being counted. After the current section of the memory device has completed testing, if ECC memory correction is enabled, the data in the buffer 104 will be analyzed on the fly to determine whether or not the corrupt data are correctable with ECC. As discussed herein, as the data is moving to the buffer 104, determination is made as to whether or not the corrupt data are correctable with ECC. Such a determination (whether ECC will be used to correct the error) may be made by determining whether or not the failures in the current section can be corrected with ECC. If the corrupted data of the defective memory portion is to be corrected with ECC, then the total number of ECC correction bits that are available for repair may be decremented.

In one embodiment, rather than decrementing a total number of ECC correction bits, the total number of correction bits may be determined by subtracting the current number of defective portions by the low threshold value. Such on-the-fly computations and evaluations may continue until the given memory section has been completely analyzed. As discussed herein, while the defective bits/bytes are not corrected at this point, the defective portions are evaluated to determine whether or not an ECC correction bit will be available during run-time to correct them later. Furthermore, redundant elements may then also be saved, so that if other memory portions fail at a later time, the redundant elements are available for further repairs.

Therefore, an exemplary auto-ECC memory correction solution may provide programmatic control over ECC memory auto-error correction capabilities. To provide for such correction capabilities, there may be two counters per ECC memory region, page, or plane. A first counter for counting failing memory portions is called a low-threshold counter, while a second counter, also counting failing memory portions, is called a high-threshold counter. These error or failure counters may be actively updated during testing of the memory device (not during post-processing steps).

The data comes streaming in from the memory module, one page at a time, which may contain several thousand bytes of information. If the memory module under test is a multiple plane device (e.g., a two-plane device), then the pages of information are received sequentially, but all at the same time. The buffer 104 will have to be large enough to handle the amount of data that will be analyzed. In one embodiment, an 8K page with 8 kilobytes of data may have 8 sectors, where each sector has 1 k of data. In one embodiment, the errors or failures of each sector are counted with a separate counter. In one embodiment, the same hardware is used, but with the old count values stored in RAM, depending on which sector is being counted. Therefore, data from a next memory sector is received and analyzed until the errors or failures of all the sectors of the page or pages are counted (each sector may have an individual count).

Each of the counters may be configured to count failures of a given device data stream per bit or per byte. This selection depends on whether the device repair is per IO or not. For example, when counting errors per bit, if there are three bits with corrupt data in a byte, there will be three errors, but when counting errors per byte, the three defective bits in the single byte will be counted as a single error. Furthermore, in one embodiment, a page is usually 8 kilobytes plus 10% more. This means that each sector is actually a little bit more than 1 k, so that a given sector may have to be broken down into two chunks of data to be evaluated. In one embodiment, there is a “main” sector and a “small” sector for each sector of the memory device. The counter, as controlled by the test result analysis processor 106, has to have the flexibility to have multiple start and stop locations. These two values (that is failure counts from a main section and a corresponding small section) are added together to evaluate a sector. In one embodiment, a start locations are determined for a main section and a small section. In one embodiment, a particular first byte begins a section, followed by a specified quantity of bits/bytes to complete the section.

ECC memory correction of the corrupt data may be applied using the following conditions: always, never, when failure counts are less than or equal to the low threshold value, or when failure counts are between the low threshold value and the high threshold value.

When ECC memory correction is eventually applied (at run-time), the corrupt data from bits or bytes to be corrected may be corrected with non-failing data. Therefore, the addresses (of the failing memory locations) of these bits/bytes that are to be corrected through ECC will have been relabeled as “good” from their original “bad” or defective portion labeling. In a best case (which can happen quite frequently), a large number of ECC memory regions with failing portions (bits/bytes) may be fully corrected. In a best case scenario (which may also occur quite frequently), a large number of ECC memory regions with failing portions are able to be fully corrected. When such an event occurs, no failure data (for the corrected regions) needs to be passed to a processor for further analysis. Test time duration may then be significantly improved.

A complication for successful ECC memory correction is that the ECC and the data regions of the device may not be adjacent. Additional hardware will allow these areas to be separated in the memory array, but conceptually reassembled for error correction purposes. This functionality allows the most accurate correction solution since error correction can apply to either the real array or the ECC memory region.

Advantages embodiments of this invention enjoy over the conventional processes may be found in test time duration improvements for the many ECC regions within a memory device where a number of bit/byte failures are correctable without the use of redundant elements (run-time correction of the device). In this case, no failure data would need to be transferred to the post-processing processor for analysis, and thus no additional time is expended searching for an optimum repair solution. A second advantage is a reduction in memory size needed to store the fail list as compared to a conventional bitmap.

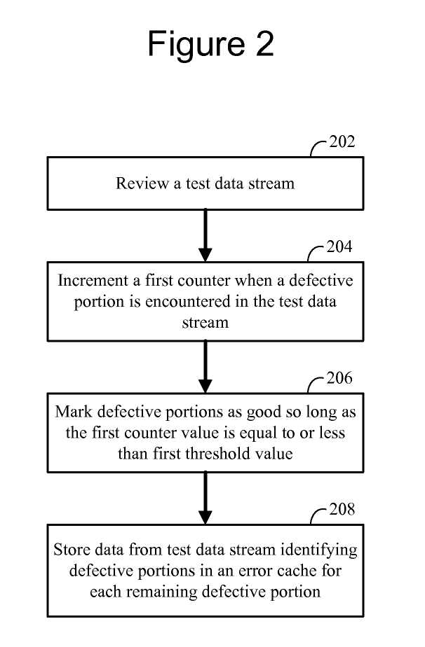

FIG. 2 illustrates computer executable steps to a process for evaluating failure data as the memory device is still being tested. In step 202 of FIG. 2, a test data stream is reviewed for failing portions. As discussed herein, a failing portion may be a defective bit or byte outputting corrupt data that results a failure or error data entry for the bit or byte. In one embodiment, the test data stream is transferred to and analyzed in a buffer. In step 204 of FIG. 2, a first counter is incremented when a defective or failing portion is encountered in the test data stream. In step 206 of FIG. 2, defective portions of the memory section contained in the failure data may be marked as “good” so long as the first counter current value is equal to or less than a first threshold value. In one embodiment, the first threshold value is equal to the total number of ECC memory corrections that are possible for the current memory region. In step 208 of FIG. 2, data from the test data stream is transferred to an error cache such that data identifying each remaining defective portion in the current section are transferred for storage in the error cache. As noted herein, if there are more ECC correction bits available than there were defective portions, then an entire memory section may be labeled as good in the error cache.

A complication for bit-wise corrections is that the number of remaining correctable bits (e.g., the low-threshold value minus the number of already corrected bits) may be smaller than the number of bits remaining in a byte that require correction. In such a case, no bits in that byte will be corrected and the address/data of defective portions are logged as failures in the fail data. If a future byte is processed that has a failing number of bits less than or equal to the remaining available correctable bits, then that byte may be corrected with some of the remaining correction bits and not logged as a failure.

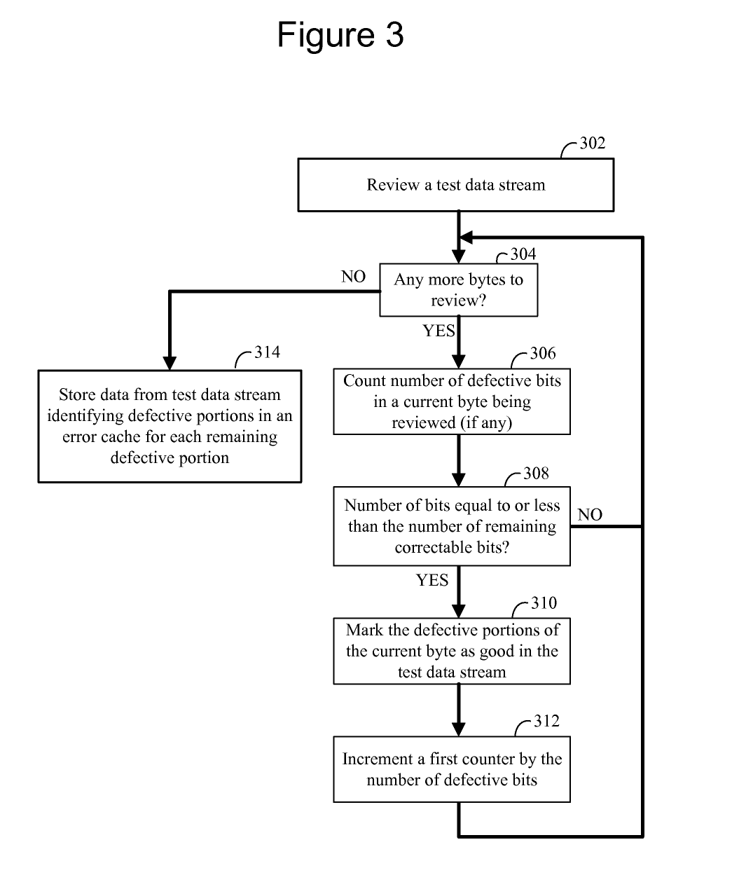

For example, FIG. 3 illustrates computer executed steps of a process for evaluating failure data for bit-wise corrections. In step 302 of FIG. 3, a test data stream for a current memory section is reviewed. In step 304 of FIG. 3, a determination is made as to whether or not there are any more bytes for review. If there are not then the process continues on to step 314. If there are more bytes to review, then the process continues on to step 306. In step 306 of FIG. 3, the number of defective bits (if any) in a current byte are counted. In step 308 of FIG. 3, a determination is made as to whether or not the number of defective bits in the current byte is less than or equal to the number of remaining correctable bits. In one embodiment, the number of remaining correctable bits in the difference between the low threshold and the current number of defects. This current number of defects may also be the current error count value. If the number of defective bits in the current byte is less than or equal to the number of remaining correctable bits, the process continues on to step 310. If the number of defective bits in the current byte is not less than or equal to the number of remaining correctable bits, the process continues back up to step 304. In step 310 of FIG. 3, the defective portions in the current byte are marked as good in the test data stream. In step 312 of FIG. 3, the first counter is incremented by the number of defective bits in the current byte (when in bit-wise mode). As illustrated in FIG. 3, after incrementing the counter, the process continues back up to step 304 to consider the next byte in the test data stream.

### Low and High Thresholds:

In accordance with embodiments of the present invention, a low threshold value is used to filter out any defective bit/byte that can be corrected by ECC memory correction. The low threshold rate establishes the total number of corrections that can be made. One purpose of these filters is to minimize how much data is captured and stored in the error cache. The low threshold may be used to remove all the ECC correctable failures and the high threshold may be used to remove massive failures, such as when a sector is badly failing. If a sector is bad, a detailed bitmap or fail list is not required.

In one embodiment, only defective portions between the two thresholds need to be saved in a fail list or other fail data. As discussed herein, the low threshold filters out the errors that are ECC correctable and the high threshold filters out massive failures. Therefore, if the total number of defective portions is either below the low threshold or above the high threshold, the data in the buffer 104 is not stored in the error cache 108, forestalling any further processing or post-processing. The sector is either marked as good or bad, respectively.

In one embodiment, a total number of defective bits/bytes may be higher than the low threshold value. Because the error correction for this sector will correct a portion of them, the counter will be decremented to get it below the low threshold. Even if the counter does not get below the threshold, the data for the correctable defective bits/bytes should still be excluded from the error cache. In other words, if the count is over the low threshold, only those bits that are over the threshold will be passed on for post-processing, because the bits of the count that are below the threshold will be corrected through ECC.

In one embodiment, error correcting capability requirements may be indicated providing an error correcting grading. For example, for a given memory controller, ECC sectors may have more or less ECC correction bits as compared to another memory controller with ECC sectors. In other words, each error correction capability has a different quantity of fail bits per sector. One benefit is that a memory controller with a larger quantity of ECC correction bits may be able to control a memory module with a large number of failing bits, but where the majority of these failing bits are correctable through ECC.

### Error Correction Filtering:

As discussed herein, conventional memory testing includes capturing failing location addresses and data for a memory module under test, followed by an analysis of various repair solutions (e.g., ECC memory correction and use of redundant elements). Conventional memory test solutions utilize full bitmaps for capturing and analyzing the memory module data. As discussed herein, a conventional bitmap can be used to map out the bits/bytes of a memory module, while a conventional fail bitmap can be used to map out the failing bits/bytes of the memory device. Such processes can require large amounts of memory to store bitmap representations of the memory device under test. Furthermore, the bandwidth needed to transfer such amounts of data can be expensive and complex. Error correction and failure data filtering, as discussed herein, addresses both of these problems with current test solutions. In one embodiment, failure filtering may take into account correctable elements of the memory module (such as ECC memory sections) in order to reduce the overall quantity of data needed to be stored and transferred to a processor for later post-processing. As also discussed herein, the data saved for post-processing may be used to determine which of the failing memory cells recorded in an error cache may be repaired with redundant elements.

In one exemplary embodiment, filtering occurs in several stages. A first stage of an exemplary filtering process counts the failures and temporarily continues storing the failures into an intermediate FIFO buffer. In one exemplary embodiment, the failures are counted by a plurality of counters. By storing just the failures into the intermediate FIFO buffer, the passing data (of memory cells that passed the memory tests) would be filtered out, leaving only the failure data of memory cells that failed the memory tests. Forming a bitmap with just the remaining data (that is, failure data) would result in the creation of a fail bitmap. In one embodiment, rather than a fail bitmap, a fail list may be used to store the failing memory locations and corresponding failure data. In one embodiment, a test data stream for one section of the memory module under test is received at a time and stored in the intermediate FIFO buffer. For example, test data for a single plane of the memory module may be received and stored in the intermediate FIFO buffer.

A second stage of the filtering process takes the data stored in the intermediate FIFO buffer after counting, and using the plurality of counters and their respective threshold values, selectively removes certain failure data from the bitmap data stream for the current section of the memory module (e.g., a memory module block, a memory module plane, and a memory module region). For a bad memory module or a bad portion of a memory module, instead of sending many data words to a processor for analysis, a simple failure statement, such as a failure header may be sent indicating that the memory module or a portion of the memory module is bad. In other words, no bitmap data or location addresses are sent. This filtering can be applied per ECC section, per repair region, per plane, or per block of a memory module. Therefore, there is never a need to store (even temporarily) more data than for a plane of a memory device (or some portion of the memory device). Storage size may be reduced, and since only bad data that does not indicate a bad memory device, section, region, plane or block is sent to a processor for post-processing analysis, the bandwidth to the post-processing processor is not critical.

In one embodiment, the second stage of the filtering process may utilize a plurality of counters operating in parallel on a memory module's bitmap data stream. As noted above, the bitmap data stream is received from automated test equipment, such as a memory tester. A counter is provided for every ECC section of the memory module. As discussed herein, a low threshold value and a high threshold value are used to provide two forms of filtering of the failure data. The high and low threshold values may be used to filter out failure data of a current section of the memory module that either can be corrected through ECC memory correction or to filter out all the failures of the current section when the quantity of failures is above the high threshold (indicating that there are more failing memory cells in the current section than can be repaired with available redundant elements). An exemplary repair region (RR) counter is provided for every repair region of the memory module. In one embodiment, each repair region provides a plurality of redundant elements to repair failing memory cells in the repair region. An exemplary total-failure counter (TFC) is also provided for every plane of the memory module. As discussed herein, filtering may occur when any combination of the various counters reaches a maximum or threshold value.

For example, up to a quantity of failing memory cells equal to the ECC section counter value can be corrected through error correction, and so their corresponding failure data may be removed from the test data stream before it is saved to the error cache RAM. However, if the ECC section counter reaches a value equal to or above the high threshold value, then there are too many failures for a combination of error correction and repair through redundant element replacement to correct; and therefore, in this situation, all of the failure data for the failing memory cells of the current memory section will be removed from the test data stream before it is saved to the error cache RAM. As discussed herein, when a section is to be listed as “bad” in the error cache RAM, a failure header may be used to indicate that a section of the memory module is bad. When a repair region counter value is at or above a threshold value, a quantity of failing memory cells is equal or greater than a quantity of redundant elements that may be used to repair failing memory cells in the repair region. Reaching this threshold value with a repair region counter may be used to indicate that more failures than can be repaired have occurred, especially if any ECC sections associated with the repair region are at or above the low threshold value. Similar failure filtering may be possible when a total-failure counter value for a plane is at or above a threshold value, especially when an associated ECC section counter is also at or above the first threshold value.

As discussed herein, failure filtering allows the filtering out of all correctable failures (through error correction with ECC sections) and then through the use of a high threshold value, the filtering out of sections of memory that have failures over the high threshold value (e.g., 25% or more bits/bytes failing in a section of memory). In other words, if there are 25% or more bits/bytes failing in a given section of memory, then the failure data for that section of memory could easily take up megabytes of error cache RAM to cover all the failures, even if the good memory cells were already filtered out. This is because a given section of memory could have a massive failure with thousands or even millions of individual failures. Therefore, when the failure rate passes a set high threshold value, no individual failure data for the given section of memory is stored in the error cache, merely a header for the section indicating the section is “bad.” As discussed herein, the use of repair region counters and total-failure counters may also be used to further filter out additional failing memory cells, when ECC section counter values are above the low threshold, but below the high threshold.

Benefits of various embodiments of failure filtering include a reduction in memory needed to store the data required to analyze and repair a memory device (or a portion of the memory device) and declare it bad. Much less bandwidth is required to send the reduced set of data. For example, a fail bitmap with filtered fail data may be significantly smaller than a full bitmap or even a conventional fail bitmap. Software redundancy analysis processes may also operate on a much smaller data set and are therefore able to come to a resolution much more quickly and so further reduce test time duration.

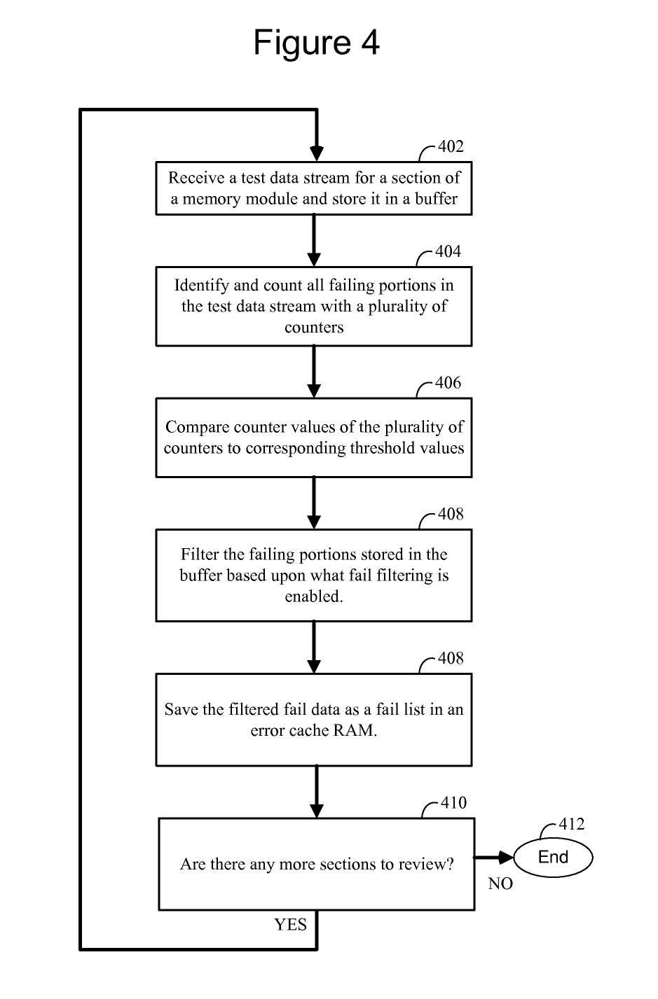

FIG. 4 illustrates exemplary computer-executed steps of an automated process for filtering failure data from a fail list. In step 402 of FIG. 4, a test data stream for a section of a memory device is received and stored in a buffer. In one embodiment, the buffer is a first-in, first-out (FIFO) buffer. In step 404 of FIG. 4, all failures identified in the test data stream for the current section are counted. In one embodiment, the failures are counted by a plurality of counters. Each failure identifies the location address for a failing bit/byte in the current memory section. In one embodiment, the plurality of counters comprises ECC section counters, repair region counters, and total-failure counters. The repair region counters and total-failure counters may accumulatively count failures in one or more sections of the memory module. In step 406 of FIG. 4, the quantities of failures as counted by the plurality of counters are compared to a plurality of corresponding thresholds. As discussed herein, ECC section counter values are compared to low threshold values and high threshold values, while repair region counter and total-failure counter values are compared to corresponding threshold values.

In step 408 of FIG. 4, the fail data stored in the buffer is filtered, based upon what filtering is enabled. In one embodiment, one or more filtering methods may be used (e.g., filtering of failing portions that may be corrected with ECC memory correction and/or filtering of identified bad sections of the memory module). In one embodiment, a current section of memory with a given number of failing portions could still be marked as a good section if the total number of failing portions is within the capabilities of an ECC correction for the section. In one embodiment, error correction filtering (that removes failing portions that are to be corrected with error correction at run time) is performed first, followed by filtering to remove a bad section from the memory module. As discussed herein, a section may comprise a block, a page, a sector, or a plane of a memory module. As also discussed herein, all failures of the current section may be removed from the test data stream when two or more counter values are above their respective thresholds. Such a section may be considered “bad” and labeled as such because of a quantity of failures counted in the section (that are beyond the ability of error correction and redundant element repairs). In one embodiment, a failure header, listing the current memory section as “bad,” may be added to the test data stream in place of the filtered out failure data.

In step 410 of FIG. 4, a determination is made as to whether or not there are any more memory sections still to be reviewed. If a test data stream has been reviewed for each of the sections of the memory module, the process continues on to step 412 of FIG. 4 and ends. If a test data stream for each section of the memory module has not yet been reviewed, the process continues back to step 402 to receive a test data stream for a next section of the memory module.

Therefore, rather than storing a full bitmap of all the location addresses and data for an entire memory module that includes both good memory cells and bad memory cells, only the bad memory cells will be saved to the error cache RAM. As also discussed herein, by further filtering out a portion of the failure data for failing portions of the memory module, the total amount of fail data saved to the error cache RAM may be further reduced. Embodiments of the present invention use a plurality of counters with a plurality of thresholds to allow any post-processing analysis to focus only on those failures that will not be corrected through ECC, so long as there are enough redundant elements available to repair the failing memory cells. In other words, massive failures would also be filtered out as they would not be a candidate for redundant section repair. Therefore, the actual locations of the failures in a section with massive failures can be ignored, with the fail list merely indicating that a particular block is failing. The end result will be a narrow band of failure data that gets passed to the error cache to be stored as a fail list.

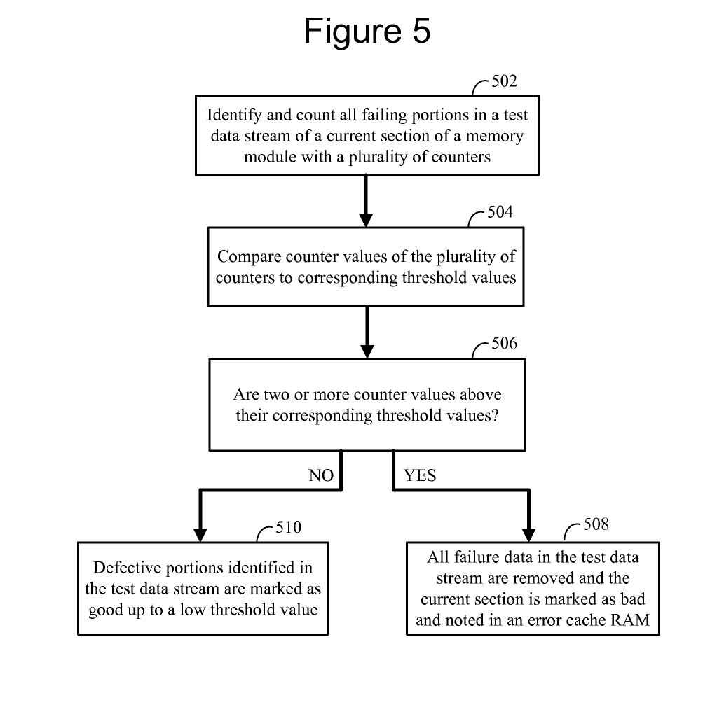

FIG. 5 illustrates exemplary computer-executed steps to an automated process for filtering failure data to optimize post-processing steps and error cache memory size. In step 502 of FIG. 5, all failing portions identified in a test data stream for a current section of a memory module are counted. As discussed herein, a plurality of counters may be used to count the failures with one or more counters accumulatively counting failures from one or more sections of the memory module. In one embodiment as discussed herein, failures are counted with ECC section counters, repair region counters and total-failure counters. In 504 of FIG. 5, the counter values of the plurality of counters are compared to their corresponding threshold values.

In step 506 of FIG. 5, if two or more counter values are above their corresponding threshold values after the memory cell failures of the current section of the memory module are all identified and counted, the process continues to step 508. Otherwise, the process will continue to step 510. In step 508 of FIG. 5, all failure data in the test data stream related to failing memory cells in the current section are removed from the test data stream and the current section is marked as bad and noted in an error cache RAM. As noted above, the failure data is replaced with a failure header for the current memory section. In step 510 of FIG. 5, defective portions identified in the test data stream for the current section are marked as good up to a low threshold value. As discussed herein, defective portions relabeled as good are removed from the test data stream and not stored in the error cache RAM (for later post-processing).

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. A method for evaluating test results for a memory module, the method comprising:
reviewing contents of a test data stream for one or more sections of the memory module;
incrementing a first counter when a defective portion is encountered in the test data stream for a first section of the one or more sections of the memory module;
marking each defective portion of the first section as good in the test data stream provided a first counter value is equal to or below a first threshold value; and
storing data from the test data stream identifying defective portions of the first section in an error cache for each remaining defective portion of the first section identified after the first counter passes a first threshold value.

2. The method of claim 1 further comprising:
correcting defective portions of the first section marked as good with error-correcting code (ECC) corrections performed during run-time.

3. The method of claim 1 further comprising:
post-processing defective portions of the first section identified in the error cache after testing to determine which defective portions of the first section are to be replaced with redundant elements.

4. The method of claim 1 further comprising correcting up to a first quantity of defective portions equal to the first threshold value with error-correcting code, and wherein data identifying the first quantity in the first section are not stored in the error cache.

5. The method of claim 1, wherein a defective portion is one of a defective bit and a defective byte.

6. The method of claim 5 further comprising:
storing data for defective portions of the first section identified before the first counter passes the first threshold value when a current total quantity of defective bits in a byte are greater than a difference between the first threshold value and a current value of the first counter, and wherein the defective bits of the byte will not increment the first counter.

7. The method of claim 1 further comprising separately counting identified defective portions for each section of the memory module.

8. The method of claim 1, wherein the data identifying the defective portions comprises one of:
a fail bitmap identifying the locations of the defective portions; and
a fail list listing the defective portions and their locations.

9. The method of claim 5, wherein a threshold value is set for each section, based upon a quantity of bits or bytes per section that are correctable through error-correction code (ECC) correction performed during run-time.

10. A memory module test apparatus comprising:
a first buffer operable to hold a test data stream for one or more sections of a memory module;
a test processor operable to review the test data stream for defective portions;
a first counter operable to increment each time the test processor encounters a defective portion in the test data stream, wherein the test processor is further operable to mark each defective portion as good in the test data stream provided a first counter value is equal to or below a first threshold value; and
an error cache operable to store data identifying the defective portions in the test data stream for each remaining defective portion identified after the first counter passes a first threshold value.

11. The test apparatus of claim 10, wherein the one or more sections of the memory module comprise error-correcting code (ECC) sections, and wherein an ECC section is operable to correct an output of the defective portions marked as good with error corrections performed during run-time.

12. The test apparatus of claim 10, wherein the test processor is further operable to post-process defective portions identified in the error cache after testing to determine which defective portions can be repaired with redundant elements.

13. The test apparatus of claim 11, wherein the error-correcting code (ECC) sections are further operable to correct up to a first quantity of defective portions equal to the first threshold value with error corrections performed during run-time, and wherein data identifying the first quantity in test data stream are not stored in the error cache.

14. The test apparatus of claim 10, wherein a defective portion is one of a defective bit and a defective byte.

15. The test apparatus of claim 14, wherein the test processor is further operable to leave a first defective portion marked as failing that was identified before the first counter passes the first threshold value when a current total quantity of defective bits in a byte are greater than a difference between the first threshold value and a current value of the first counter, wherein the first defective portion is stored in the error cache, and wherein the defective bits of the byte will not increment the first counter.

16. The test apparatus of claim 1, wherein the first counter is further operable to separately count identified defective portions for each section of a plurality of sections of the memory module.

17. The test apparatus of claim 10, wherein the data identifying the defective portions comprises one of:
a fail bitmap identifying the locations of the defective portions; and
a fail list listing the defective portions and their locations.

18. The test apparatus of claim 14, wherein a threshold value is set for each section, based upon a quantity of bits or bytes per section that are correctable through error correction.

19. A computer readable media comprising computer-executable instructions stored therein for evaluating test results for a memory module, the computer-executable instructions comprising:
instructions to review a test data stream for one or more sections of the memory module;
instructions to increment a first counter when a defective portion is encountered in the test data stream for a first section of the one or more sections of the memory module;
instructions to mark each defective portion of the first section as good in the test data stream provided a first counter value is equal to or below a first threshold value; and
instructions to store data from the test data stream identifying defective portions of the first section in an error cache for each remaining defective portion of the first section identified after the first counter passes a first threshold value.

20. The computer-readable media of claim 19, wherein the computer-executable instructions further comprise instructions to correct defective portions of the first section marked as good with error-correcting code (ECC) corrections performed during run-time.

21. The computer-readable media of claim 19, wherein the computer-executable instructions further comprise instructions to post-process defective portions of the first section identified in the error cache after testing to determine which defective portions of the first section are to be replaced with redundant elements.
